(19) United States
(12) Patent Application Publication
(10) Pub. No.: US 2007/0281221 A1
(43) Pub. Date: Dec. 6, 2007

(54) STENCIL MASK

(75) Inventor: Tokushige Hisatsugu, Tokyo (JP)

Correspondence Address: INGRASSIA FISHER & LORENZ, P.C., 7150 E. CAMELBACK, STE. 325, SCOTTSDALE, AZ, 85251, US

(73) Assignee: HOLON CO., LTD., Tokyo (JP)

(21) Appl. No.: 11/755,707

(22) Filed: May 30, 2007

(30) Foreign Application Priority Data
Jun. 1, 2006 (JP) 2006-153072

(51) Int. Cl. G03F 1/00; G03C 5/00

(52) U.S. Cl. 430/5; 430/296; 430/942

(57) ABSTRACT

A stencil mask (10) for use in electron beam projection exposure includes a silicon base plate (12), an insulating film (14) formed on the silicon base plate, and a silicon film (16) formed on the insulating film. In the silicon base plate and the insulating film, an opening (18) penetrating them is provided; in the silicon film, a plurality of holes (20) penetrating it and continuous to the opening are provided. In the silicon base plate and the insulating film, at least one hole (22) penetrating them is provided, and in this hole, an electrically conducting substance (24) contacting the silicon base plate and the silicon film is disposed.

### TECHNICAL FIELD

The present invention relates to a stencil mask for use in electron beam projection exposure, and more particularly, to electron beam proximity exposure.

### BACKGROUND

Electron beam proximity exposure is used as means to print an image of a fine geometrical pattern such as a wiring pattern of a semiconductor integrated circuit on a surface of a material such as a silicon wafer.

In the electron beam proximity exposure, to print or transcribe an image of a geometrical pattern on the surface of the material, an electron beam is applied to a mask (stencil mask) provided with a plurality of holes corresponding to the geometrical pattern, and a resist coated on the surface of the material is exposed to the electron beam which passed through the holes of the stencil mask.

FIG. 5 shows a structure of a stencil mask 100 heretofore used in electron beam proximity exposure.

The stencil mask 100 comprises a silicon base plate 102, an insulating film 104 formed on the silicon base plate, and a silicon film 106 formed on the insulating film. The silicon base plate 102 and the insulating film 104 are provided with an opening 108 penetrating them, and the silicon film is provided with a plurality of holes 110 corresponding to the geometrical pattern continuous to the opening 108.

Also, the stencil mask 100, having a very thin thickness, is usually reinforced by a plate-like mask holder 112 which is adhered to the silicon base plate 102. The mask holder 112 is provided with an opening 114 continuous to the opening 108.

The electron beam emitted from an electron beam emitter (not shown) passes through the opening 114 of the mask holder 112, the silicon base plate 102, and the opening 108 of the insulating film 104 successively, and after passing through the plural holes 110 of the silicon film 106, arrives at the resist of the material.

Since the silicon film 106 of the stencil mask 100 is insulated from the silicon base plate 102 by the insulating film 104, electrons stay in the silicon film 106, accompanying the passage of the electron beam.

Since the electrons which stayed in the silicon film 106 become a factor to prevent the electron beam from passing in the holes 110 of the silicon film 106, in the conventional stencil mask 100 the silicon film 106 and the silicon base plate 102 are electrically connected by a conductive substance 116 so as to introduce the staying electrons from the silicon film 106 to the silicon base plate 102.

The conductive substance 116 is disposed in one or more positions in the circumference of the silicon base plate 102 and the silicon film 106 and in contact with the circumference of the positions. However, since the silicon film 106 is too thin (0.5 to 2 μm thick) to ensure a sufficient contact area with the conductive substance 116, so that the staying electrons in the silicon film 106 cannot be reduced sufficiently.

While it is conceivable to dispose the conductive substance 116 so as to contact the entire circumferential surface of the silicon film 106 so as to increase the contact area, it is not suitable, for it causes deformation of the stencil mask. It is also conceivable to dispose the conductive substance 116 in order to increase the contact area to contact, in addition to the circumferential surface of the silicon film 106, to a part of its surface. However, this is not suitable, because the conductive substance 116 provided on the surface of the silicon film 106 disturbs ensuring a necessary distance between the silicon film 106 of the stencil mask and the resist as an object of exposure in the electron beam proximity exposure.

### BRIEF SUMMARY

An object of the present invention is to provide a stencil mask for electron beam projection exposure capable of sufficiently reducing staying electrons.

The present invention relates to a stencil mask for use in an electron beam projection exposure, which comprises: a silicon base plate; an insulating film formed on the silicon base plate; a silicon film formed on the insulating film; an opening provided in and penetrating the silicon base plate and the insulating film; a plurality of holes provided in the silicon film, penetrating the silicon film and continuous to the opening; at least one hole provided in the silicon base plate and the insulating film and penetrating them; and a conductive substance disposed in the hole and contacting the silicon base plate and the silicon film.

Another stencil mask according to the present invention comprises: the silicon base plate; the insulating film; the silicon film, the opening provided in the silicon base plate and the insulating film; a plurality of holes provided in the silicon film; at least one hole or groove provided in and penetrating the insulating film and the silicon film; and a conductive substance disposed in the hole or groove and contacting the silicon base plate and the silicon film.

According to the present invention, a position or positions to dispose the conductive substance in contact with the silicon base plate and the silicon film are made at least one hole penetrating the silicon base plate and the insulating film, or at least one groove or hole penetrating the insulating film and the silicon film. So, regardless of the thickness of the silicon film, the size or the number of the holes can be freely set, and the contact area of the conductive substance relative to the silicon film can be made greater. Also, since the conductive substance is to be accommodated inside the hole which is a space within the stencil mask, when applying the stencil mask of the present invention to the electron beam proximity exposure, there is no disturbance in ensuring a distance between the silicon film and an object to be exposed.

### BRIEF DESCRIPTION OF THE DRAWINGS

FIG. 1 is a plan view of an example of the stencil mask of the present invention.

FIG. 2 is a section obtained along the line 2-2 in FIG. 1

FIG. 3 is a bottom view of another example of the stencil mask of the present invention.

FIG. 4 is a section obtained along the line 4-4 in FIG. 3.

FIG. 5 is a section of a conventional stencil mask.

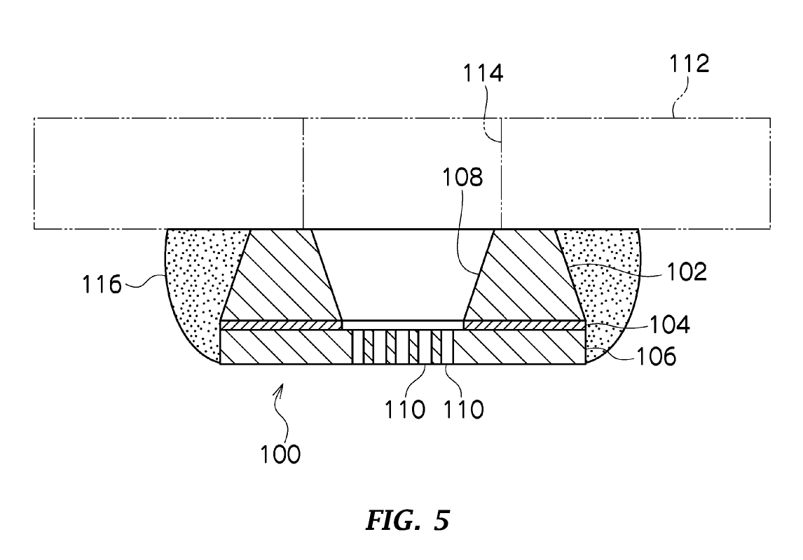

### DETAILED DESCRIPTION

### Embodiment

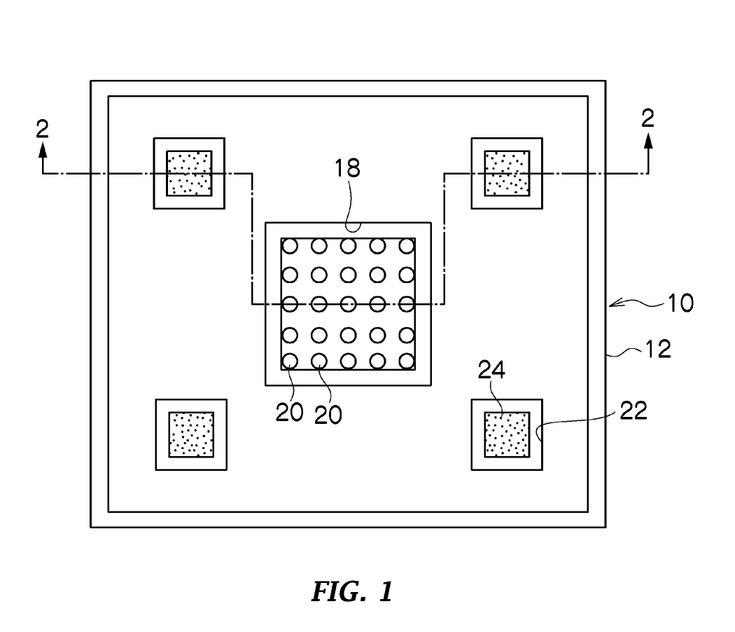

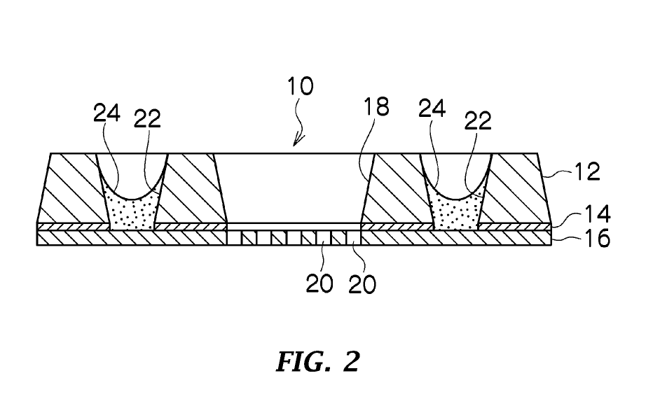

Referring to FIGS. 1 and 2, the stencil mask according to an example of the present invention is generally shown by the reference numeral 10.

The stencil mask 10 as illustrated generally has a rectangular planar shape and comprises, as in a conventional one: a silicon base plate 12 which is a base plate made of silicon (Si); an insulating film 14 made of SiO₂, SiN and the like formed on the silicon base plate (in more detail, its underside as seen in FIG. 2); a silicon film 16 formed in the insulating film (in more detail, its underside as seen in FIG. 2); an opening 18 provided in and penetrating the silicon base plate 12 and the insulating film 14; and a plurality of holes 20 provided in the silicon film 12, penetrating the silicon film, and continuous to the opening 18. Also, as in the conventional one, a mask holder (not shown) for reinforcing the stencil mask 10 is mounted on the silicon base plate 12. The mask holder has an opening communicated to the opening 18.

The plural holes 20 formed in the silicon film 16 form a geometrical pattern like a wiring pattern of a semiconductor integrated circuit to be transcribed onto a material such as a silicon wafer in the electron beam projection exposure like an electron beam proximity exposure.

In the electron beam projection exposure, an electron beam is emitted from an electron supply source to the stencil mask 10 for transcription of the geometrical pattern. The emitted electron beam passes through the opening 18 of the stencil mask, through the plural holes 20 of the silicon film 16, and arrives at the resist coated on the material and exposes it.

At this time, part of electrons in the electron beam passing through the holes 20 of the silicon film 16 stay in the silicon film 16. The staying electrons, which subsequently prevents the electron beam passing through the holes 20 from advancing, should be removed.

In the present invention, to remove the staying electrons in the silicon film 16, at least one (four in the illustration) hole 22 is provided in the silicon base plate 12 and the insulating film 14 to penetrate them, and a conductive substance 24 is disposed in the hole or holes to contact the silicon base plate 12 and the silicon film 16.

Four holes 22 respectively have a rectangular planar shape and are disposed at the four corners of a rectangular silicon base plate 12. The number of the holes 22, their planar shapes and sizes can be freely set instead of the illustrated example.

The conductive substance 24 is made of a metal having a low-melting point, an adhesive or the like having a conductivity. The adhesive, when charged to fill all of the holes 22, induces splits in the silicon base plate 12. To avoid it, the adhesive is disposed in the holes 22, so that its upside may draw a downward parabola as seen in the section in FIG. 2.

The electrons staying in the silicon film 16 accompanying a passage of the electron beam are moved through the conductive substance 24 from the silicon film 16 to the silicon base plate 12, thereby removing the staying electrons from the silicon film 24.

The ability to remove the staying electrons depends on the size of the contact area of the conductive substances 24. The contact area can be changed by varying the size of an opening area according to the number of holes where the conductive substance 24 is disposed and the sizes of the opening areas of the holes relative to the silicon film 16.

The hole 22 is formed with a part of both the silicon base plate 12 and the insulating film 14 removed to form interior spaces of the silicon base plate 12 and the insulating film 14. Also, the conductive substance 24 is accommodated in these interior spaces. Therefore, it is possible to avoid conventional problems caused by disposing the conductive substance outside the stencil mask 10, namely, problems in the electron beam proximity exposure to disturb ensuring a distance between the silicon film 16 of the stencil mask and the resist which is an object to be exposed.

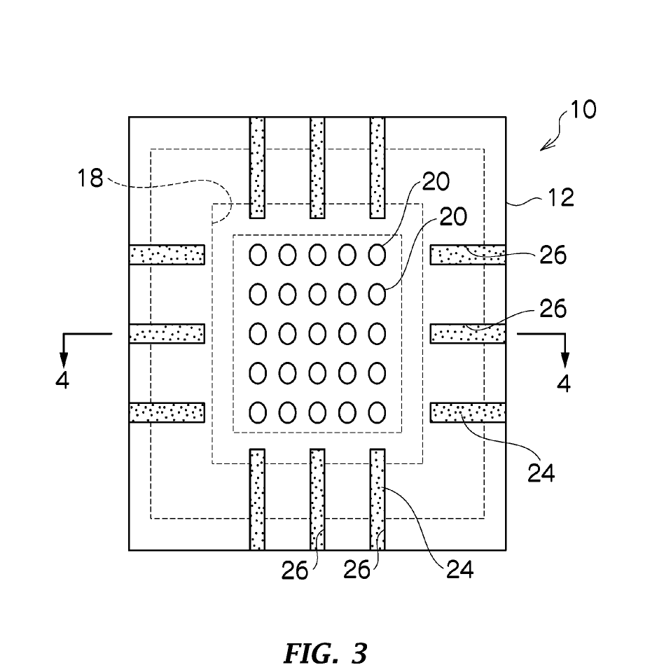

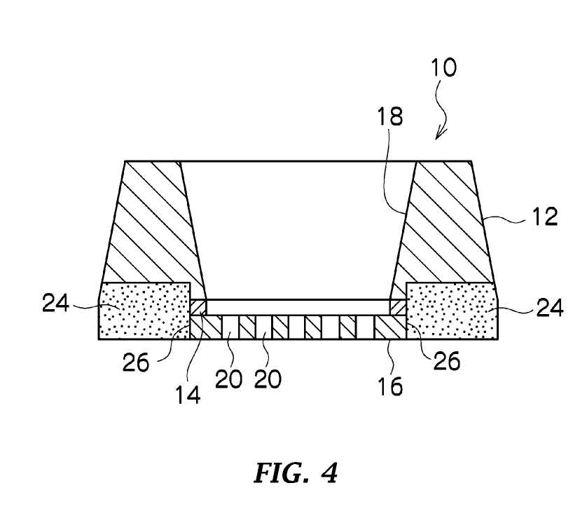

In place of the above example, as shown in FIGS. 3 and 4, it is possible to provide at least one groove 26 (twelve in the illustration) penetrating the insulating film 14 and the silicon film 16 and dispose in the groove the conductive substance 24 which contacts the silicon base plate 12 and the silicon film 16. In this example, the groove 26 is formed by further cutting off a part of the silicon base plate 12.

According to this example, it is possible to move the electrons staying in the silicon film 16 to the silicon base plate 12 through the conductive substance 24 disposed in each groove 26.

As in the examples shown in FIGS. 1 and 2, the number and size (widthwise or lengthwise dimension) of the groove 26 can be changed, thereby setting the capacity to exclude the staying electrons from the silicon film 16 to a desired one. In this example, the groove 26 constitutes an interior space of the stencil mask 10. Also, the groove 26 opening in the circumferential surfaces of both the silicon film 16 and the insulating layer 14 as well as the circumferential surface of the silicon base plate 12 may be replaced with an opening (not shown) not opening in these circumferential surfaces. The number, sizes, shapes, etc. of the holes can be freely set.

What is claimed is:

1. A stencil mask for use in electron beam projection exposure, comprising:
a silicon base plate;
an insulating film formed in said silicon base plate;
a silicon film formed in said insulating film;
an opening provided in and penetrating said silicon base plate and said insulating film;
a plurality of holes provided in said silicon film, penetrating said silicon film, and continuous to said opening;
at least one hole provided in and penetrating said silicon base plate and said insulating film; and
a conductive substance disposed in said hole and contacting said silicon base plate and said silicon film.

2. A stencil mask for use in electron beam projection exposure, comprising:
a silicon base plate;
an insulating film formed in said silicon base plate;
a silicon film formed in said insulating film;
an opening provided in and penetrating said silicon base plate and said insulating film;
a plurality of holes provided in said silicon film, penetrating said silicon film, and continuous to said opening;
at least one hole or groove provided in and penetrating said insulating film and said silicon film; and
a conductive substance disposed in said hole or groove and contacting said silicon base plate and said silicon film.
